(19) United States
(12) Patent Application Publication
(10) Pub. No.: US 2007/0011535 A1
(43) Pub. Date: Jan. 11, 2007

(54) Semiconductor integrated circuit

(76) Inventors: Kenichi Anzou, Kawasaki-shi (JP); Chikako Tokunaga, Yokohama-shi (JP)

Correspondence Address: DLA PIPER RUDNICK GRAY CARY US, LLP, 2000 UNIVERSITY AVENUE, E. PALO ALTO, CA, 94303-2248, US

(21) Appl. No.: 11/088,413

(22) Filed: Mar. 23, 2005

(30) Foreign Application Priority Data
Mar. 29, 2004 (JP) P2004-96637

(51) Int. Cl. G01R 31/28

(52) U.S. Cl. 714/733

(57) ABSTRACT

A semiconductor integrated circuit includes a plurality of memories; a BIST circuit configured to test at least one of the memories; and a plurality of shift circuits connected to each of the memories, each of the shift circuits shifts one of first data bits obtained from at least one of the memories and a second data bits having a smaller number of bits than the first data bits, in synchronization with an external clock, by electing one of the first and second data bits in accordance with a swiching signal from the BIST circuit; wherein the shift circuits are connected to one another so as to form a part of a serial shift path.

### CROSS REFERENCE TO RELATED APPLICATIONS AND INCORPORATION BY REFERENCE

This application is based upon and claims the benefit of priority from the prior Japanese Patent Applications No. P2004-096637, filed on Mar. 29, 2004; the entire contents of which are incorporated herein by reference.

### BACKGROUND OF THE INVENTION

1. Field of the Invention

The present invention relates to a semiconductor integrated circuit, and, more particularly, relates to a semiconductor integrated circuit including Buit-In Self Test (BIST) circuit.

2. Description of the Related Art

As an inspection method of a memory in a semiconductor integrated circuit, in general, a BIST of the memory is performed by a BIST circuit. A “comparator BIST” is known, which compares memory output data read out from the memory to the expected data with each other, and determines the presence of faults, if any. As another method, a “compactor BIST” is known, which compacts the memory output data read out from the memory in a BIST circuit, and determines the presence of the faults based on a result of the compaction.

Another method performs a fault diagnosis that identifies a fault location represented as the bit position of the memory by use of a BIST circuit. As shown in FIG. 11, in the case of using a comparator BIST circuit 901, respective memory output capture registers 931 to 93n and comparison flag registers 951 to 95n of respective memory collars 911 to 91n are serially connected to an address register 902 of an unillustrated address generator and a pass/fail flag register 903 in the BIST circuit 901. Thus, one circular shift path 900 is provided as a whole.

At the time of the fault diagnosis, a BIST operation is first executed, and memory output data individually read out from memories 921 to 92n are each captured in the memory output capture registers 931 to 93n. The memory output data captured in the memory output capture registers 931 to 93n and an expected value of the memory output data from the BIST circuit 901 are compared with each other by comparators 941 to 94n, and results of the comparisons are individually captured in the comparison flag registers 951 to 95n. Defect detection is performed for the memories in the BIST circuit 901 based on the comparison results captured in the comparison flag registers 951 to 95n, and results of the defect detection are captured in the pass/fail flag register 903.

Then, the BIST operation is interrupted, and by use of the circular shift path 900, signal states of the memory output capture registers 931 to 93n, the comparison flag registers 951 to 95n, the address register 902 and the pass/fail flag register 903 are shifted out through an external output terminal 904. The BIST is resumed after the end of the shift out, and states of the registers of the shift path 900 is shifted out at the next readout timing of the BIST operation. In order to return to a state where the BIST operation is interrupted, the shift path 900 is circularly configured such that original address data is captured in the address register 902. The interruption of the BIST operation, the shift out, and the resumption of the BIST operation are repeated, and thus internal states of the memories 921 to 92n are read out. Based on read out results, a fail bit map showing faulty bit positions of cell arrays of the memories is generated, and bit positions of faulty locations of the memories 921 to 92n are identified.

However, in a semiconductor integrated circuit shown in FIG. 11, in addition to a memory output capture register and a comparison flag register which correspond to a memory subjected to the fault diagnosis, memory output capture registers and comparison flag registers which correspond to memories which are not subjected to the fault diagnosis must be shifted. Accordingly, the testing time is greatly increased. Moreover, it is also possible that the size of a test pattern for performing the fault diagnosis will be too large to fit in a memory of a testing apparatus.

### SUMMARY OF THE INVENTION

An aspect of the present invention inheres in a semiconductor integrated circuit including a plurality of memories; a BIST circuit configured to test at least one of the memories; and a plurality of shift circuits connected to each of the memories, each of the shift circuits shifts one of first data bits obtained from at least one of the memories and a second data bits having a smaller number of bits than the first data bits, in synchronization with an external clock, by electing one of the first and second data bits in accordance with a swiching signal from the BIST circuit; wherein the shift circuits are connected to one another so as to form a part of a serial shift path.

### BRIEF DESCRIPTION OF DRAWINGS

FIG. 1 is a circuit diagram shown an example of a semiconductor integrated circuit according to a first embodiment of the present invention.

FIG. 2 is a circuit diagram shown an example of a BIST unit according to the first embodiment of the present invention.

FIG. 3 is a shematic view showing an example of a BIST configration register according to the first embodiment of the present invention.

FIG. 4 is a circuit diagram shown an example of signal flows of BIST when whole of memories of the semiconductor integrated circuit are to be subjected to BIST according to the first embodiment of the present invention.

FIG. 5 is a circuit diagram shown an example of signal flows of BIST when a partially of memories of the semiconductor integrated circuit are to be subjected to the BIST according to the first embodiment of the present invention.

FIG. 6 a circuit diagram shown an example of signal flows of fault diagnosis of a semiconductor integrated circuit according to the first embodiment of the present invention.

FIG. 7 is a circuit diagram shown an example of a semiconductor integrated circuit according to a modification of the present invention.

FIG. 8 is a circuit diagram shown an example of a semiconductor integrated circuit according to a second embodiment of the present invention.

FIG. 9 is a circuit diagram shown an example of a semiconductor integrated circuit according to a third embodiment of the present invention.

FIG. 10 is a circuit diagram shown an example of a BIST unit according to the third embodiment of the present invention.

FIG. 11 is a circuit diagram showing a semiconductor integrated circuit in prior art.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set fourth such as specific signal values, etc. to provide a thorough understanding of the present invention. However, it will be obvious to those skilled in the art that the present invention may be practiced without such specific details. In other instances, well-known circuits have been shown in block diagram form in order not to obscure the present invention in unnecessary detail.

### First Embodiment

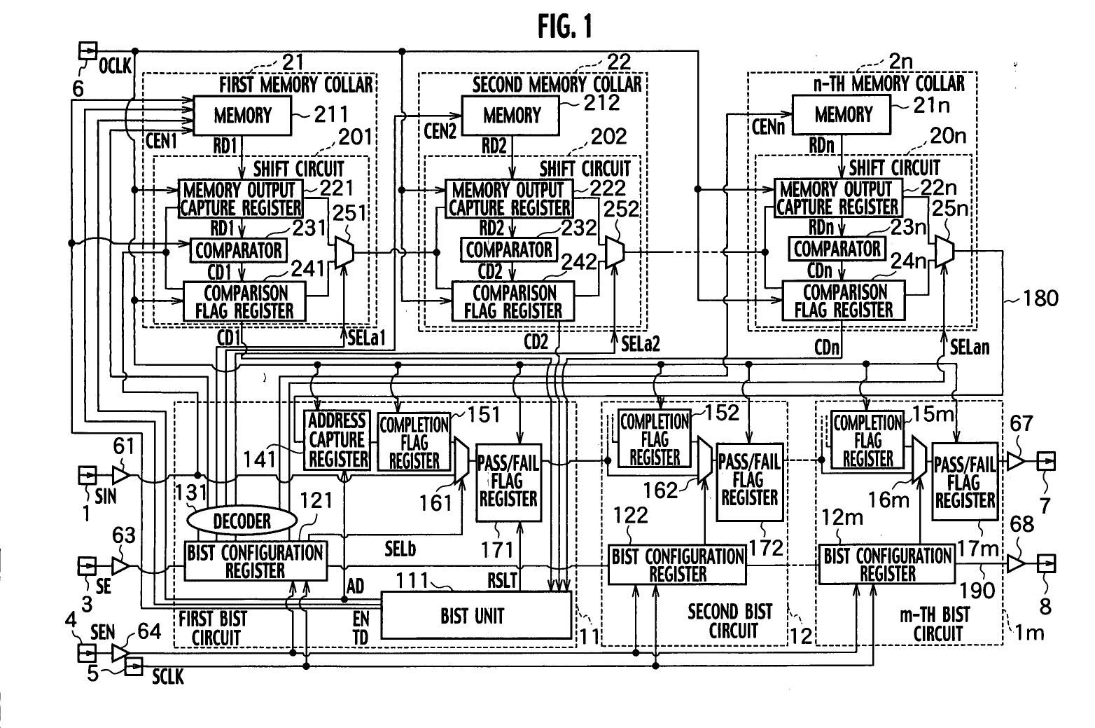

As shown in FIG. 1, a semiconductor integrated circuit according to a first embodiment of the present invention includes a plurality of memories (embedded memories) 211 to 21n (n: integer of 1 or more), a BIST circuit (first BIST circuit) 11 configured to test at least one of the memories 211 to 21n, and a plurality of shift circuits 201 to 20n connected to each of the memories 211 to 21n, each of the shift circuits 201 to 20n shifts one of first data bits obtained from at least one of the memories and a second data bits having a smaller number of bits than the first data bits, in synchronization with an external clock OCLK, by electing one of the first and second data bits in accordance with swiching signals (memory-side swiching signals) SELa1 to SELan from the BIST circuit 11. The shift circuits 201 to 20n are connected to one another so as to form a part of a serial shift path 180.

The plurality of shift circuits 201 to 20n respectively include memory output capture registers 221 to 22n which capture memory output data RD1 to RDn read out from the memories 211 to 21n and shift the memory output data RD1 to RDn as the first data bits in synchronization with the external clock OCLK. Also included are comparators 231 to 23n which compare the memory output data RD1 to RDn captured in the memory output capture registers 221 to 22n with an expected value of the memory output data RD1 to RDn transmittd from the BIST circuit 11. Comparison flag registers 241 to 24n capture comparison results CD1 to CDn, in which the numbers of bits are respectively smaller than the numbers of bits of the memory output data RD1 to RDn output from the comparators 231 to 23n, and shift the comparison results CD1 to CDn in synchronization with the external clock OCLK. Memory-side switching circuits 251 to 25n which, in response to the memory-side switching signals SELa1 to SELan, serially elect one of the memory output data RD1 to RDn shifted from the memory output capture registers 221 to 22n and the comparison results CD1 to CDn shifted from the comparison flag registers 241 to 24n.

Each of the memory output capture registers 221 to 22n and the comparison flag registers 241 to 24n may be a part of a larger shift register.

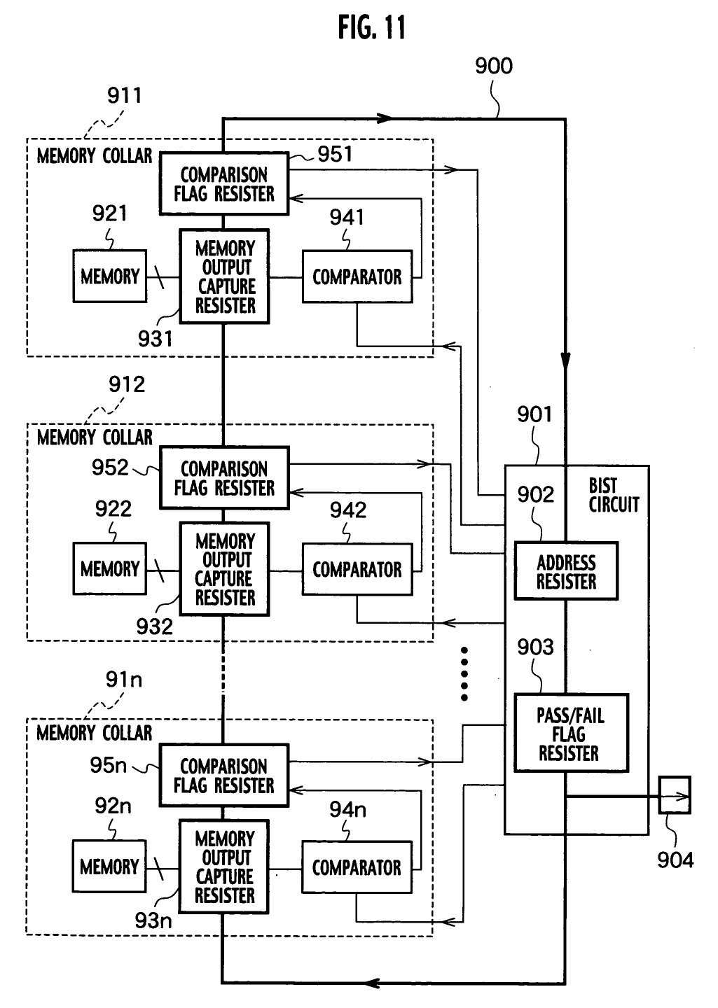

In the semiconductor integrated circuit shown in FIG. 11, the comparison flag registers 951 to 95n and the memory output capture registers 931 to 93n are serially connected to each other. The semiconductor integrated circuit shown in FIG. 1 is different from the semiconductor integrated circuit shown in FIG. 11 in the following points. In FIG. 1, the memory-side switching circuit 251 is connected to the memory output capture register 221 and comparison flag register 241 of the shift circuit 201. The memory output capture register 222 and comparison flag register 242 of the shift circuit 202 are connected to the memory-side switching circuit 251. The memory-side switching circuit 252 is connected to the memory output capture register 222 and the comparison flag register 242. In a similar way, the subsequent switching circuits are connected to the memory output capture registers and the comparison flag registers, and the memory output capture register 22n and comparison flag register 24n of the shift circuit 20n are connected to an unillustrated memory-side switching circuit 25(n-1). Moreover, the memory-side switching circuit 25n is connected to the memory output capture register 22n and the comparison flag register 24n.

The plurality of memories 211 to 21n are accommodated in a plurality (first to n-th) of memory test collars (hereinafter called “memory collars”) 21 to 2n, respectively. The plurality of shift circuits 201 to 20n respectively configured to be connected to the memories 211 to 21n are also included in the memory collars 21 to 2n. Moreover, the semiconductor integrated circuit includes second to m-th (m: integer of 3 or more) BIST circuits 12 to 1m, and a plurality of unillustrated memory collars connected to the second to m-th BIST circuits 12 to 1m, respectively.

Among the shift circuits 201 to 20n shown in FIG. 1, which are connected to the first BIST circuit 11, in the forefront shift circuit 201, a common shift path input terminal 1 is connected to the memory output capture register 221 and comparison flag register 241. In the endmost shift circuit 20n, the first BIST circuit 11 is connected to the memory-side switching circuit 25n. A common external clock input terminal 6 is connected to the memory output capture registers 221 to 22n and comparison flag registers 241 to 24n of the shift circuit 201 to 20n.

The first to m-th BIST circuits 11 to 1m are comparator-based BIST circuits. The first BIST circuit 11 includes: a BIST unit 111 connected to the memory 211 in the first memory collar 21 and the memories 212 to 21n in the second to n-th memory collars 22 to 2n without illustrating wiring; a BIST configration register 121 connected to the serial setting input terminal 3; a decoder 131 connected in pallarel to the BIST configration register 121, and the memories 211 to 21n and memory-side switching circuits 251 to 25n in the first to n-th memory collars 21 to 2n; an address capture register 141 connected to the memory-side switching circuit 25n in the n-th memory collar 2n and the BIST unit 111; a completion flag register 151 connected to the address capture register 141; a BIST-side switching circuit 161 connected to each of the respective completion flag register 151, the BIST configration register 121 and a shift path input terminal 1; and a pass/fail flag register 171 connected to each of the respective BIST-side switching circuit 161 and the BIST unit 111.

In response to a second switching signal (BIST-side switching signal) SELb, the first BIST circuit 11 assigns one of a shift path (first path) including the address capture register 141, the completion flag register 151 and the pass/fail flag register 171, which are connected to the shift circuit 20n, and a shift path (second path) including the pass/fail flag register 171, in which the number of bits of signals is smaller than that of signals in the first path, such that one of the shift paths can form a part of the serial shift path 180 to an external output.

The address capture register 141, completion flag register 151 and pass/fail flag register 171 of the first BIST circuit 11 are individually connected to the common external clock input terminal 6. Unillustrated address capture registers, completion flag registers 152 to 15m and pass/fail flag registers 172 to 17m of the second to m-th BIST circuits 12 to 1m are also individually connected to the common external clock input terminal 6. Note that, besides such common use of the external clock input terminal 6, a plurality of terminals similar to the external clock input terminal 6, which input external clocks, may be provided. Moreover, the BIST configration registers 121 to 12m of the first to m-th BIST circuits 11 to 11m are individually connected to common setting enable input terminal 4 and setting clock input terminal 5. Note that buffers 61, 63, 64, 67 and 68 for buffering various signals are connected to the shift path input terminal 1, the serial setting input terminal 3, a setting enable input terminal 4, a shift path output terminal 7 and a serial setting output terminal 8, respectively.

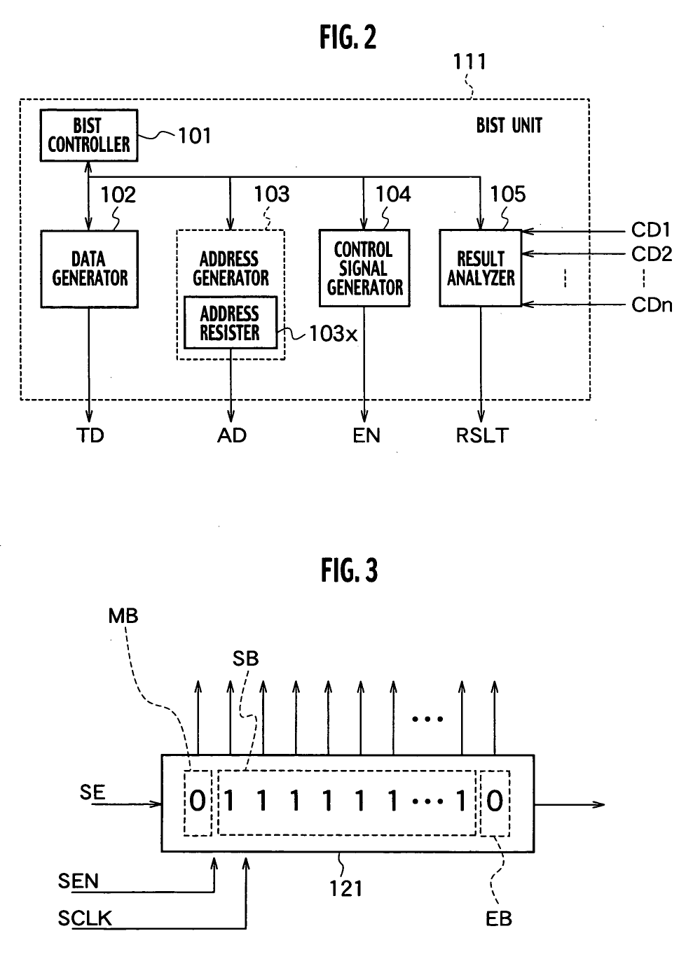

As shown in FIG. 2, the BIST unit 111 of the first BIST circuit 11 includes a BIST controller 101, and a data generator 102, an address generator 103, a control signal generator 104 and a result analyzer 105, which are individually connected to the BIST controller 101. As shown in FIG. 1, the data generator 102, the address generator 103 and the control signal generator 104 are individually connected to the memory 211 of the first memory collar 21, and also connected to the memories 212 to 21n of the second to n-th memory collars 22 to 2n through unillustrated wiring. The data generator 102 shown in FIG. 2 is also connected to the comparator 231 of the first memory collar 21, and is also connected to the comparators 232 to 23n of the second to n-th memory collars 22 to 2n through unillustrated wiring. The result analyzer 105 shown in FIG. 2 is connected to the comparison flag register 241 of the first memory collar 21, is also connected to the comparison flag registers 242 to 24n of the second to n-th memory collars 22 to 2n through unillustrated wiring, and is also connected to the pass/fail flag register 171.

The BIST controller 101 shown in FIG. 2 controls the respective data generator 102, address generator 103, control signal generator 104 and result analyzer 105 to sequentially generate signals. The data generator 102 generates a signal TD providing memory write data and an expected value of the memory output data. The address generator 103 generates memory address data AD. The control signal generator 104 generates a memory control signal EN. The generated memory write data TD, memory address data AD and memory control signal EN are transmitted to each of the memories 211 to 21n of the first to n-th memory collars shown in FIG. 1. Moreover, the expected value TD is transmitted to the comparators 231 to 23n of the first to n-th memory collars 21 to 2n. For example, the result analyzer 105 shown in FIG. 2 examines the existance of defects in the memories 211 to 21n in response to the comparison results CD1 to CDn from the comparison flag registers 241 to 24n of the first to n-th memory collars 21 to 2n shown in FIG. 1. Note that each of the unillustrated BIST units of the second to m-th BIST circuits 12 to 1m shown in FIG. 1 has a similar configuration to that of the BIST unit 111 shown in FIG. 2, and accordingly, repetitive description will be omitted.

The BIST configration register 121 of the first BIST circuit 11 shown in FIG. 1 is serially connected to the BIST configration register 122 of the second BIST circuit 12. In a similar way, the BIST configration registers are serially connected to one another, and the BIST configration register 12(m-1) of the BIST circuit 1(m-1) of the unillustrated (m-1)-th BIST circuit 1(m-1) is serially connected to the BIST configration register 12m of the endmost m-th BIST circuit 1m. The BIST configration register 12m is connected to the serial setting output terminal 8. Specifically, between the serial setting input terminal 3 and the serial setting output terminal 8, a serial shift path 190 is provided by the BIST configration registers 121 to 12m of the first to m-th BIST circuits 11 to 11m.

The BIST configration registers 121 to 12m are storage elements in which a bit string is stored in advance or the bit string is set through the serial setting input terminal 3. Each of the BIST configration registers 121 to 12m shift a setting shift signal SE serially input from the serial setting input terminal 3 in synchronization with a setting clock SCLK from the setting clock input terminal 5 when a shift enable signal SEN from the setting enable input terminal 4 is in an enabled state. As a result, values of the respective bits included in the BIST configration registers 121 to 12m are set. The BIST configration registers 121 to 12m are serially connected to one another, and accordingly, it is not necessary to add external input/output terminals to each of the BIST configration registers 121 to 12m, and external input/output terminals required for the setting can be restricted to a minimum.

For example, as shown in FIG. 3, the BIST configration register 121 includes the operation mode setting bit MB, a memory selecting bit string SB, and an operation enable bit EB. The operation mode setting bit MB is a bit for switching a BIST and a fault diagnosis. At the time of the BIST, the operation mode setting bit MB is set to “0”. Meanwhile, at the time of the fault diagnosis, the operation mode setting bit MB is set to “1”.

The memory selecting bit string SB selects a memory to be subjected to the BIST or the fault diagnosis from among the memories 211 to 21n of the first to n-th memory collars 21 to 2n shown in FIG. 1. Here, bits of the memory selecting bit string SB individually correspond to the memories 211 to 21n one to one. Bits corresponding to the memories to be subjected to the BIST or the fault diagnosis are set to “1”. Meanwhile, bits corresponding to memories which are not to be subjected to the BIST or the fault diagnosis are set to “0”. Note that each of the bits of the memory selecting bit string SB may correspond not only to one memory but also to a group of a plurality of memories (for example, two memories 211 and 212).

Furthermore, the operation enable bit EB shown in FIG. 3 is a bit for setting whether the first BIST circuit 11 shown in FIG. 1 is to be subjected to the BIST at the time of the BIST or to the fault diagnosis at the time of the fault diagnosis. When the first BIST circuit 11 is not to be subjected to the BIST or the fault diagnosis, the operation enable bit EB is set to “0”. When the first BIST circuit 11 is to be subjected to the BIST or the fault diagnosis, the operation enable bit EB is set to “1”. Each of the BIST configration registers 122 to 12m shown in FIG. 1 has a similar configuration to that of the BIST configration register 121 shown in FIG. 3, and accordingly, repetitive description will be omitted.

The decoder 131 of the first BIST circuit 11 shown in FIG. 1 transmits chip enable signals CEN1 to CENn to the respective memories 211 to 21n in response to values set in the operation mode setting bit MB and the memory selecting bit string SB which are shown in FIG. 3, thereby controlling the respective states of the memories 211 to 21n. For example, when the memory 211 is to be subjected for the BIST or the fault diagnosis, and the first bit of the memory selecting bit string SB is set to “1”, the decoder 131 controls the chip enable signal CEN1 of the memory 211 is turned on. When the memory 211 is not to be subjected to the BIST or the fault diagnosis, and the first bit of the memory selecting bit string SB is set to “0”, the decoder 131 controls the chip enable signal CEN1 of the memory 211 is turned off. Here, when the first BIST circuit 11 shifts the shift path (second path) in which the number of bits is smaller, the chip enable signals CEN1 to CENn of the memories 211 to 21n, which are objects of the first BIST circuit 11 are controlled to turn off. Note that the decoder 131 may control clock signals transmitted to the respective memories 211 to 21n in place of the chip enable signals CEN1 to CENn.

As shown in FIG. 1, the decoder 131 transmits the memory-side switching signals SELa1 to SELan to the respective memory-side switching circuits 251 to 25n in response to the bits set in the operation mode setting bit MB and the memory selecting bit string SB which are shown in FIG. 3, thereby controlling switching of the respective memory-side switching circuits 251 to 25n. For example, in order to subject the first BIST circuit 11 to the BIST or the fault diagnosis, the decoder 131 shown in FIG. 1 allows the BIST-side switching circuit 161 to transmit a value from the completion flag register 151 when the operation enable bit EB shown in FIG. 3 is set to “1”. In order not to subject the first BIST circuit 11 to the BIST or the fault diagnosis, as shown in FIG. 1, the decoder 131 allows the BIST-side switching circuit 161 to transmit an external shift signal SIN from the shift path input terminal 1 when the operation enable bit EB shown in FIG. 3 is set to “0”.

As shown in FIG. 1, the address capture register 141 in the first BIST circuit 11 captures the memory address data AD from the address register 103x in the BIST unit 11 shown in FIG. 2. Furthermore, in synchronization with the external clock OCLK from the external clock input terminal 6, the address capture register 141 captures value transmitted from the memory-side switching circuit 25n in the n-th memory collar 2n, and shifts the memory address data AD to the completion flag register 15.

The completion flag register 151 of the first BIST circuit 11 holds a completion flag for identifying that the first BIST circuit 11 operates normally at the time of the BIST operation and that the BIST operation completes. The completion flag register 151 receives a value from the address capture register 141 and shifts the completion flag in synchronization with the external clock OCLK from the external clock input terminal 6.

The BIST-side switching circuit 161 of the first BIST circuit 11 switches and transmits the value from the completion flag register 151 and the external shift signal SIN from the shift path input terminal 1 in response to the BIST-side switching signal SELb from the BIST configration register 121. For example, when the BIST-side switching signal SELb is “0”, the BIST-side switching circuit 161 selects the external shift signal SIN. When the BIST-side switching signal SELb is “1”, the BIST-side switching circuit 161 selects the value from the completion flag register 151.

As shown in FIG. 1, the pass/fail flag register 171 of the first BIST circuit 11 captures a defect detection result RSLT from the BIST unit 111. Moreover, the pass/fail flag register 171 receives the value from the BIST-side switching circuit 161 and shifts the defect detection result RSLT in synchronization with the external clock OCLK from the external clock input terminal 6.

The pass/fail flag register 171 of the first BIST circuit 11 is connected to the switching circuit 162 of the second BIST circuit 12. In a similar way, the subsequent pass/fail flag registers are connected to the switching circuits, and the pass/fail flag register 17(m-1) of the unillustrated m-th BIST circuit 1(m-1) is connected to the switching circuit 16m of the endmost m-th BIST circuit 1m. A pass/fail flag register 17m of them-th BIST circuit lm is connected to the shift path output terminal 7. Note that unillustrated decoders and address capture registers, the completion flag registers 152 to 15m, the switching circuits 162 to 16m and the pass/fail flag registers 172 to 17m have substantially similar configurations to those of the decoder 131, address capture register 141, completion flag register 151, BIST-side switching circuit 161 and pass/fail flag register 171 of the first BIST circuit 11, respectively. Accordingly, repetitive description will be omitted.

The memory 211 of the first memory collar 21, in response to the memory write data TD, the memory address data AD, and the memory control signal EN from the first BIST unit 111, output the memory output data RD1. The memory output capture register 221 captures the memory output data RD1 read out from the memory 211. Furthermore, the memory output capture register 221 captures the external shift signal SIN from the shift path input terminal 1, and shifts the memory output data RD1, in synchronization with the external clock OCLK, from the external clock input terminal 6.

The comparator 231 of the first memory collar 21 compares the memory output data RD1 from the memory output capture register 221 with the expected value TD from the BIST unit 111 in the first BIST circuit 11, and then output comparison result CD1. The comparison flag register 241 in the first memory collar 21 captures the comparison result CD1 from the comparator 231. Furthermore, the comparison flag register 241 captures the external shift signal SIN from the shift path input terminal 1, and shifts the comparison result CD1, in synchronization with the external clock OCLK, from the external clock input terminal 6.

In response to the memory-side switching signal SELa1 from the decoder 131 of the first BIST circuit 11, the memory-side switching circuit 251 of the first memory collar 21 elects one of the value shifted from the memory output capture register 221 and the value shifted from the comparison flag register 241. Configurations of the second to n-th memory collars 22 to 2n connected to the first BIST circuit 11 and configurations of unillustrated memory collars individually connected to the second to m-th BIST circuits 12 to 1m are substantially similar to the configuration of the first memory collar 21. Accordingly, repetitive description will be omitted.

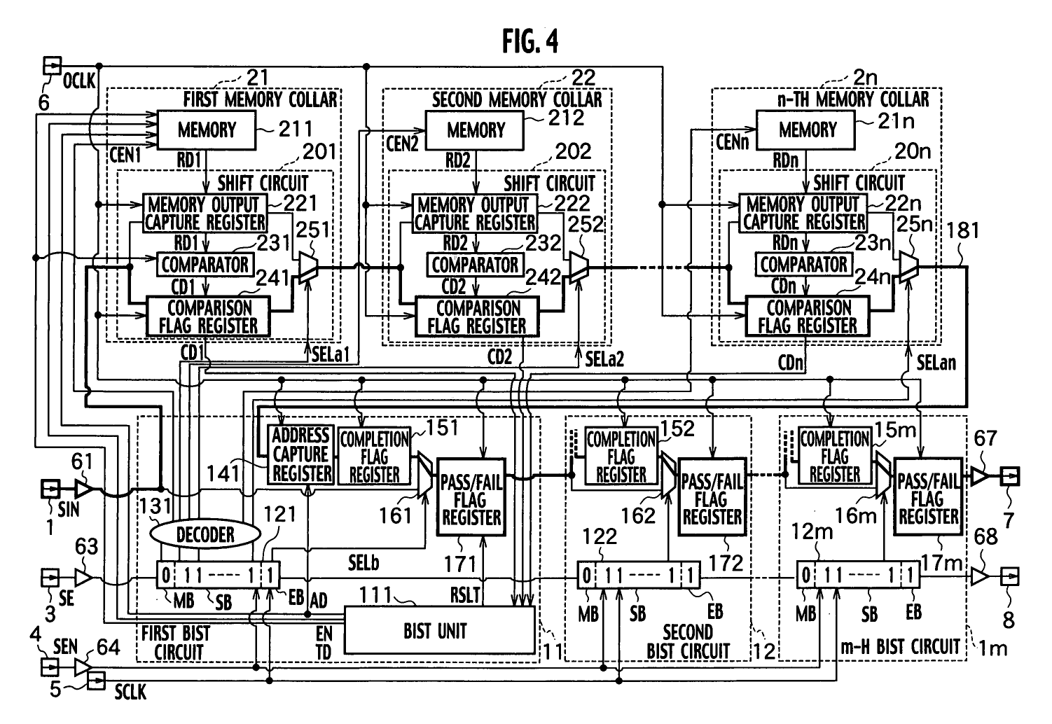

Next, operations in the case of the BIST for all of the memories 211 to 21n connected to the first BIST circuit 11 and all of the unillustrated memories individually connected to the second to m-th BIST circuits 12 to 1m in the semiconductor integrated circuit shown in FIG. 1 will be described referring to FIG. 4.

As shown in FIG. 4, the setting shift signal SE is serially input from the serial setting input terminal 3, and because the operation mode is a BIST mode, the values of the operation mode setting bits MB of the respective BIST configration registers 121 to 12m of the first to m-th BIST circuits 11 to 1m are set to “0”. All of the memories 211 to 21n connected to the first BIST circuit 11 and all of the unillustrated memories respectively connected to the second to m-th BIST circuits 12 to 1m are to be subjected to the BIST. Accordingly, all of the values of the memory selecting bit string SB of the BIST configration registers 121 to 12m are set to “1”. Furthermore, the first to m-th BIST circuits 11 to 1m are to be subjected to the BIST. Accordingly, the operation enable bits EB of the BIST configration registers 121 to 12m are set to “1”.

At the time of the BIST operation, the decoder 131 of the first BIST circuit 11 controls, in the “on” state, the chip enable signals CEN1 to CENn transmited to the memories 211 to 21n of the first to n-th memory collars 21 to 2n, which are to be subjected to the BIST. The signal TD providing the memory write data and the expected value, the memory address data AD, and the memory control signal EN, which are output from the BIST unit 111, are transmitted to the memories 211 to 21n of the first to n-th memory collars 21 to 2n. The memory output data RD1 to RDn are read out from the memories 211 to 21n, respectively, and are captured in the memory output capture registers 221 to 22n. The comparators 231 to 23n individually compare the memory output data RD1 to RDn from the respective memory output capture registers 221 to 22n with the expected value TD from the BIST unit 111. The comparison flag registers 241 to 24n individually capture the comparison results CD1 to CDn from the comparators 231 to 23n. In response to the comparison results CD1 to CDn captured in the comparison flag registers 241 to 24n, the defect detection are performed by the BIST unit 111 of the first BIST circuit 11, and the defect detection result RSLT of all of the memories 211 to 21n is output. The defect detection result RSLT is captured in the pass/fail flag register 171 shown in FIG. 4. In a way similar to the first BIST circuit 11 and the first to n-th memory collars 21 to 2n connected to the first BIST circuit 11, also in the second to m-th BIST circuits 12 to 1m and the unillustrated memory collars respectively connected to the second to m-th BIST circuits 12 to 1m, BIST operations for all of the memories in the memory collar are executed.

When a configration code is input, sides with the comparison flag registers 241 to 24n are elected. The respective BIST-side switching circuits 161, 162 . . . , and 16m are controlled to output the values from the completion flag registers 151, 152 . . . , and 15m. Specifically, as shown in FIG. 4, the respective comparison flag registers 241 to 24n of the first to n-th memory collars 21 to 2n form a part of a serial shift path 181 in between the shift path input terminal 1 and the shift path output terminal 7. The address capture register 141 of the first BIST circuit 11, the respective unillustrated address capture registers of the second to m-th BIST circuits 12 to 1m, the respective completion flag registers 151 and 152 to 15m and pass/fail flag registers 171 and 172 to 17m of the first to m-th BIST circuits 11 to 1m are provided in another part of the shift path 181. The values of the shift path 181 are shifted in synchronization with the external clock from the external clock input terminal 6, and are shifted out through the shift path output terminal 7. The fault is analyzed externally based on the comparison results CD1 to CDn, the defect detection result RSLT and the like.

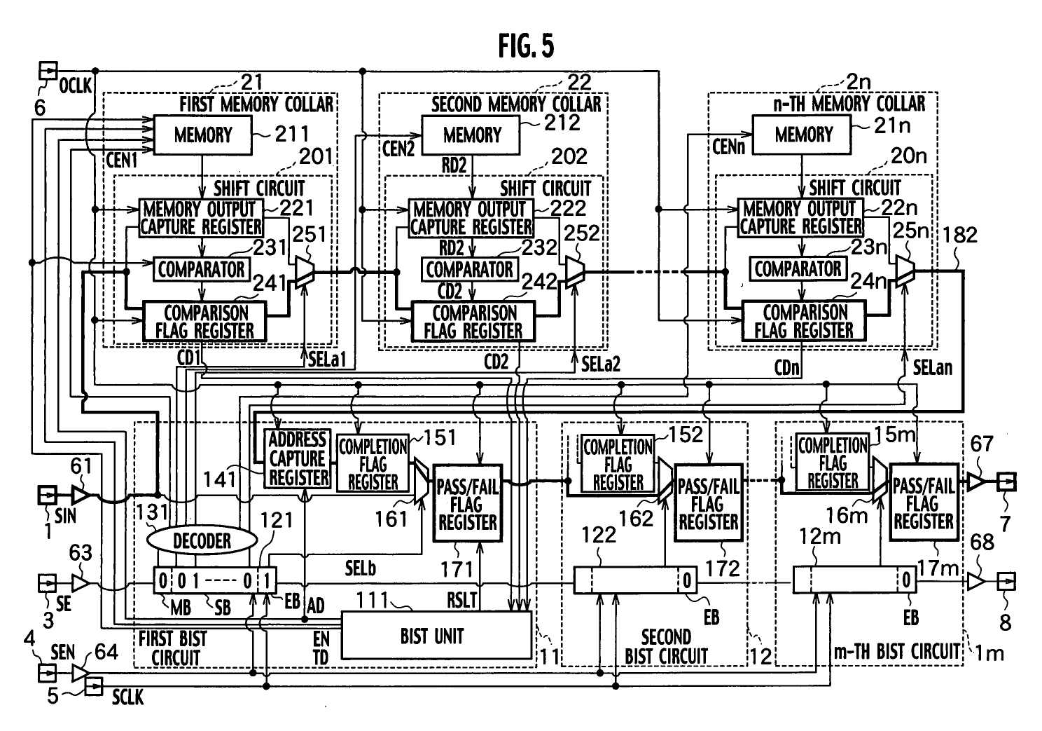

Next, operations in the case of the BIST only for the memory 212 of the second memory collar 22 in the semiconductor integrated circuit shown in FIG. 1 will be described referring to FIG. 5.

As shown in FIG. 5, first, the setting shift signal SE is serially input from the serial setting input terminal 3, and because the operation mode here is the BIST mode, the operation mode setting bit MB of the first BIST circuit 11 is set to “0”. Moreover, since the memory 212 is to be subjected to the BIST, only the second bit from the input side in the memory selecting bit string SB, which corresponds to the memory 212, is set to “1”. The first BIST circuit 11 is to be subjected to the BIST, and accordingly, the operation enable bit EB is set to “1”. The operation enable bits EB of the respective BIST configration registers 122 to 12m of the second to m-th BIST circuits 12 to 1m, which are not to be subjected to the BIST, are set to “0”.

At the time of the BIST operation, only the chip enable signal CEN2 transmitted to the memory 212 of the second memory collar 22, which is to be subjected to the BIST, is controlled to turn on, and the BIST operation is executed. From the BIST unit 111 of the first BIST circuit 11, the memory write data TD, the memory address data AD and the memory control signal EN are transmitted to the memory 212 of the second memory collar 21. Here, the chip enable signals individually transmitted to the memories 211 to 21n, excluding the memory 212, and to the unillustrated memories connected to the second to m-th BIST circuits 12 to 1m, which are not to be subjected to the BIST, are controlled to turn off. Accordingly, the BIST operations are not executed there. The memory output data RD2 read out from the memory 212 of the second memory collar 22 is captured in the memory output capture register 222. The comparator 232 compares the memory output data RD2 from the memory output capture register 222 with the expected value TD, which is from the BIST unit 111. The comparison flag register 242 captures the comparison result CD2 from the comparator 232. In response to the comparison result CD2 captured in the comparison flag register 242, the BIST circuit 111 determines the existence of defects in the memory 212. The pass/fail flag register 171 captures the defect detection result RSLT from the result analyzer 105 of the BIST unit 111.

When a configration code is input, sides with the comparison flag registers 241 to 24n are elected. Moreover, the BIST-side switching circuit 161 of the first BIST circuit 11 selects the value from the completion flag register 151. The respective switching circuits 162 to 16m of the other second to m-th BIST circuits 12 to 1m select the values from the pass/fail flag registers 171 to 17(m-1) of the first to (m-1)-th BIST circuits 11 to 1(m-1) (the (m-1)-th BIST circuit (m-1) and the pass/fail flag register 17(m-1) are unillustrated). Specifically, between the shift path input terminal 1 and the shift path output terminal 7, an entire serial shift path 182 is composed of a shift path including the comparison flag registers 241 to 24n in the first to n-th memory collars 21 to 2n, a shift path including the address capture register 141, the completion flag register 151 and the pass/fail flag register 171 in the first BIST circuit 11, and a shift path including the respective pass/fail flag registers 172 to 17m of the second to m-th BIST circuits 12m to 1m. Here, the external shift signal SIN is input from the shift path input terminal 1 to the shift path 182, a shift operation is serially performed in synchronization with the external clock OCLK, and a value of the shift path 182 is shifted out through the shift path output terminal 7. Note that values of all of the comparison flag registers 241 to 24n of the first to n-th memory collars 21 to 2n and values of the comparison flag registers of the unillustrated memory collars connected to the second to m-th BIST circuits 12 to 1m also appear on the shift path 182. However, the external pass/fail determination has to be performed only for the comparison result CD2 of the comparison flag register 242 corresponding to the memory 212 to be subjected to the BIST.

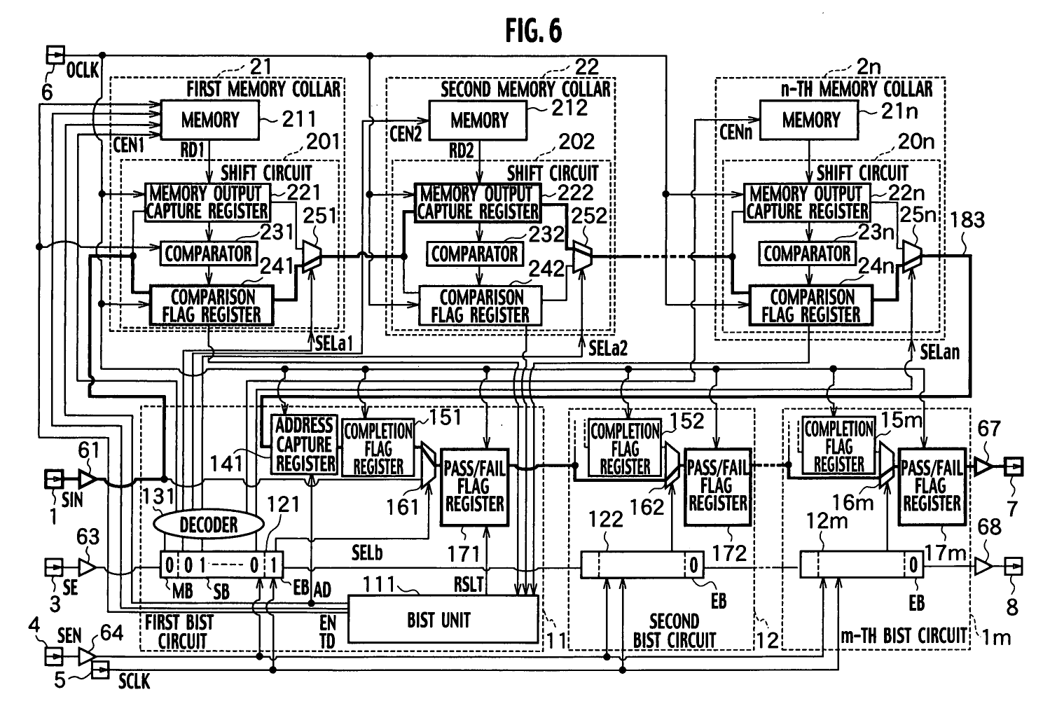

Next, operations in the case of the fault diagnosis, for example, for the memory 212 of the second memory collar 22 in the semiconductor integrated circuit shown in FIG. 1 will be described referring to FIG. 6.

As shown in FIG. 6, because the operation mode here is a fault diagnosis mode, the setting shift signal SE input from the serial setting input terminal 3, sets the operation mode setting bit MB of the BIST configration register 121 of the first BIST circuit 11 to “1”. On the premise that the fault diagnosis is performed only for the second memory 212 from the input side, only one bit corresponding to the memory 212 to be subjected to the fault diagnosis in the memory selecting bit string SB is set to “1”. Moreover, since the first BIST circuit 11 is to be subjected to the fault diagnosis, the operation enable bit EB is set to “1”. Furthermore, the operation enable bits EB of the respective BIST configration registers 122 to 12m of the second to m-th BIST circuits 12 to 1m, which are not to be subjected to the fault diagnosis, are set to “0”.

At the time of the BIST operation, the chip enable signal transmitted only to the memory 212, to be subjected to the fault diagnosis, is controlled to turn on, and the BIST operation is executed. From the BIST unit 111, the memory write data TD, the memory address data AD and the memory control signal EN are generated, and are transmitted to the memory 212. The memory output data RD2 read out from the memory 212 is captured in the memory output capture register 222. The BIST operation is interrupted every time when the memory output is captured by each address. The chip enable signals individually input to the memories 211 and 213 to 21n excluding the memory 212 and the unillustrated memories individually connected to the second to m-th BIST circuits 12 to 1m are controlled to turn off, and the BIST operations are not executed there.

When a configration code is input, the memory-side switching circuit 252 of the shift circuit 202 selects the value from the memory output capture register 222. The memory-side switching circuits 251 and 253 to 25n excluding the memory-side switching circuit 252 selects the values from the comparison flag registers 241 and 243 to 24n, respectively. The BIST-side switching circuit 161 selects the value from the completion flag register 151. The switching circuits 162 to 16m select the values from the pass/fail f-lag registers 171 to 17(m-1) (the pass/fail flag register 17(m-1) is not illustrated). Specifically, between the shift path input terminal 1 and the shift path output terminal 7, an entire serial shift path 183 composes a shift path including the memory output capture register 222 of the second memory collar, a shift path including the comparison flag registers 241 and 243 to 24n excluding the comparison flag register 242 in the first to n-th memory collar registers 21 to 2n excluding the second memory collar 22, a shift path including the address capture register 141, the completion flag register 151 and the pass/fail flag register 171 in the first BIST circuit 11, and a shift path including the pass/fail flag registers 172 to 17m in the second to m-th BIST circuits 12 to 1m. Here, a shift operation is performed for the shift path 183 in synchronization with the external clock OCLK, and values of the shift path 183 are shifted out through the shift path output terminal 7.

After completing the shift out, the BIST operation is resumed, and the values of the shift path 183 are shifted out again at the next readout timing. As for the memory address data AD, a value held in an address register 103x of the address generator 103 of the first BIST circuit 11 shown in FIG. 2 is not directly shifted, but as shown in FIG. 6, the value captured in the address capture register 141 is output. Accordingly, an address held in the address register 103x shown in FIG. 2 is not changed, and therefore, as shown in FIG. 6, the shift path 183 does not have to be circularly configured like the shift path 900 shown in FIG. 11. The interruption of the BIST operation, the shift out, and the resumption of the BIST operation are repeated, and thus the internal state of the memory is read out every time when the readout operation from the memory 212 is performed. Based on results of the data shifted out, a fail bit map showing faulty bit positions of cell arrays of the memory 212 is created, and the fault analysis is performed.

According to the semiconductor integrated circuit shown in FIG. 1, as shown in FIG. 5, at the time of the BIST, the chip enable signals individually transmitted, for example, to the memories 211 to 21n of the first BIST circuit 11 excluding the memory 212, which are not to be subjected to the BIST, and to the unillustrated memories connected to the second to m-th BIST circuits 12 to 1m, which are not to be subjected to the BIST, are turned off. Accordingly, the BIST operations are not executed. Therefore, at the time of the BIST, consumption of unnecessary power is restricted. Moreover, the memory 212 to be subjected to the BIST can be arbitrarily selected externally by use of the BIST configration registers 121 to 12m. Accordingly, scheduling of the test considering power consumption and the time required for the BIST can be performed even after the first to m-th BIST circuits 11 to 1m are installed in the semiconductor integrated circuit.

As shown in FIG. 6, also at the time of the fault diagnosis, the shift path 183 partially composes only one bit of each of the comparison flag registers 241 and 243 to 24n excluding the comparison flag register 242 in the memory collars 21 and 23 to 2n excluding the second memory collar 22, which include the memories 211 to 21n excluding the memory 212, the memories 211 to 21n not being subjected to the fault diagnosis. Furthermore, the shift path 183 partially composes only one bit of each of the pass/fail flag registers 172 to 17m in the second to m-th BIST circuits 12 to 1m which are not to be subjected to the fault diagnosis. Accordingly, steps required for the shift can be reduced, the time required for the fault diagnosis can be substantially shortened, and the size of a test pattern can be reduced. Moreover, the chip enable signals transmitted to the memories which are not to be subjected to the fault diagnosis are turned off, and do not operate. Therefore, power consumption can be reduced.

Note that, though an example of subjecting only the memory 212 to the fault diagnosis has been described with reference to FIG. 6, it is also possible to simultaneously subject a plurality of memories. For example, the plurality of memories 211 to 21n can undergo the fault diagnosis. Moreover, to perform the BIST against all of the memories 211 to 21n and the unillustrated memories, an initiation circuit may be established such that the BIST configration registers 121 to 12m are set in a state to subject all of the memories 211 to 21n and the unillustrated memories to the BIST at the time of initializing the first to m-th BIST circuits 11 to 1m.

Moreover, though the first to m-th BIST circuits 11 to l1 have been shown in FIG. 1, the number of BIST circuits is not limited. The number of memories individually connected to the first to m-th BIST circuits 11 to 1m are also not particularly limited. The first to m-th BIST circuits 11 to l1 can test on one or more memories connected to the each first to m-th BIST circuits. Though the first to n-th shift circuits 201 to 20n have been shown, the number of shift circuits only has to correspond to the number of memories. Furthermore, though the single shift paths 180 to 183 have been shown in FIG. 4 to FIG. 6, a plurality of shift paths may be provided.

(Modification)

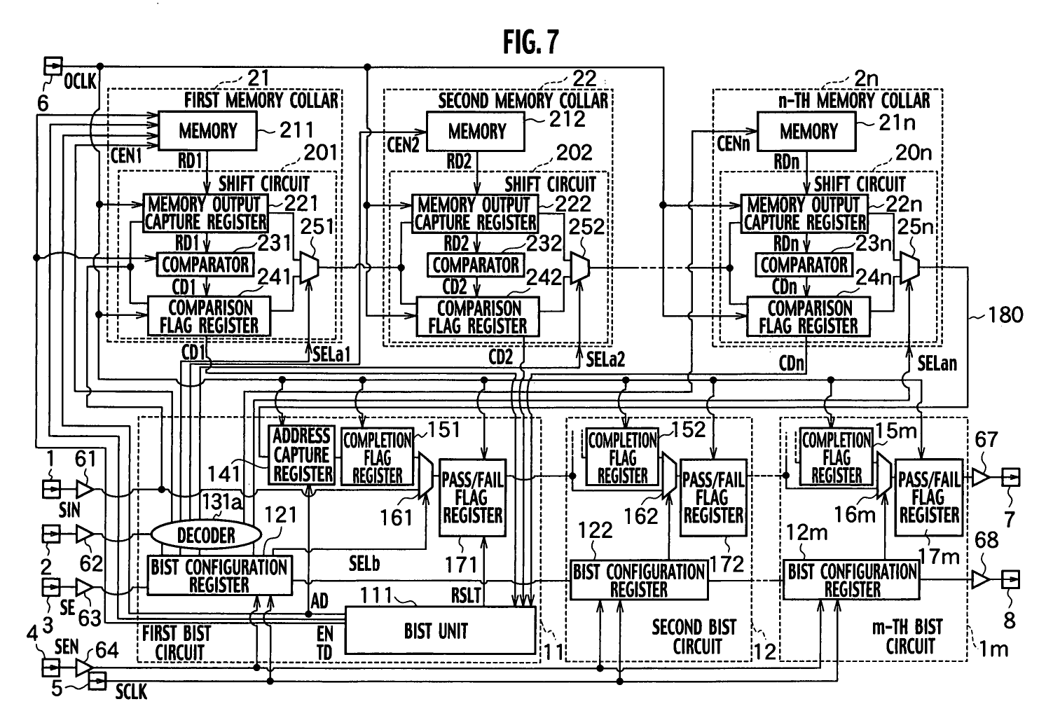

As shown in FIG. 7, a semiconductor integrated circuit according to a modification of the first embodiment of the present invention is different from the semiconductor integrated circuit shown in FIG. 1 in further including a decoder control input terminal 2 connected to a decoder 131a of the first BIST circuit 11. A buffer 62 which buffers signal values from the decoder control input terminal 2 is connected to the decoder control input terminal 2.

Irrespective of the parallel output values from the BIST configration register 121 shown in FIG. 1, the decoder 131a transmits the chip enable signals CEN1 to CENn to the memories 211 to 21n of the first to n-th memory collars 21 to 2n, respectively, in response to a decode control signal DCTR from the decoder control input terminal 2, thereby controlling the chip enable signals CEN1 to CENn respectively transmitted to the memories 211 to 21n in the “on” state or the “off” state. For example, when the decoder control signal DCTRL is “1”, the decoder 131a sets all of the memories 211 to 21n to be subjected to the BIST. Note that the decoder 131a may control the clock signals transmitted to the memories 211 to 21n in place of the chip enable signals CEN1 to CENn. Unillustrated decoders in the second to m-th BIST circuits 12 to l1 may also be connected to the decoder control input terminal 2. Since the other configurations are substantially similer to the semiconductor integrated circuit shown in FIG. 1, a redundant description will be omitted.

According to the modification of the first embodiment of the present invention, the decoder 131a controls the chip enable signals CEN1 to CENn respectively transmitted to the memories 211 to 21n in the “on” state or the “off” state in response to a decoder control signal DCTR from the decoder control input terminal 2. Thereby, it is possible to reduce the shifting time in the bits for the setting operation before BIST execution.

### Second Embodiment

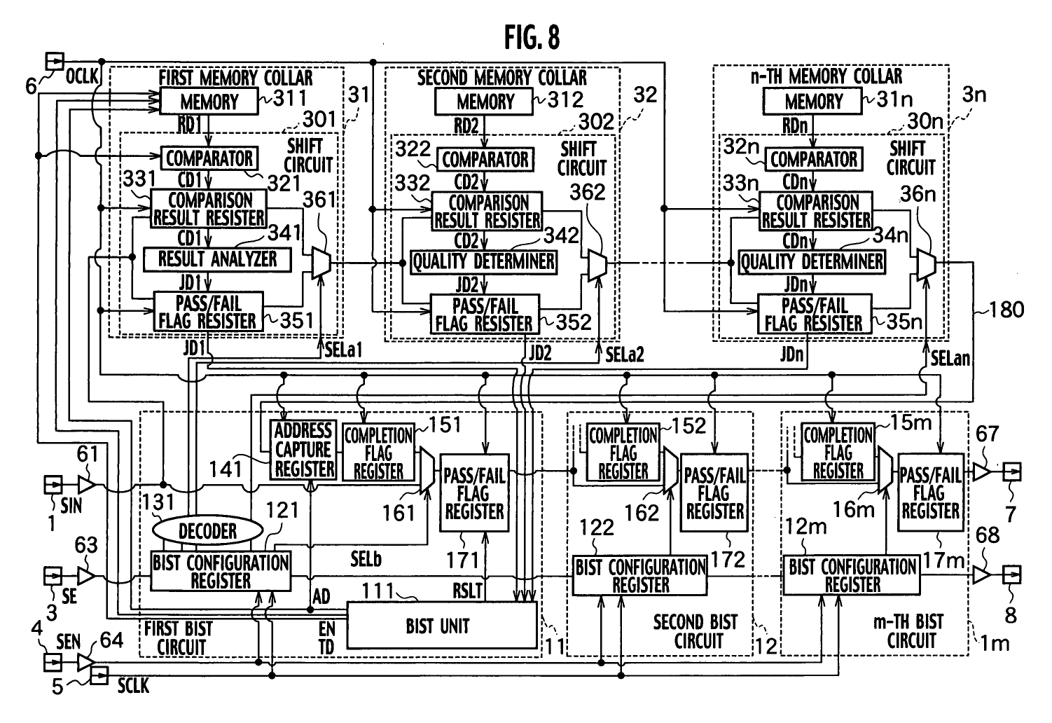

A semiconductor integrated circuit according to a second embodiment of the present invention is different from the semiconductor integrated circuit according to the first embodiment in the following point. Specifically, unlike the shift circuits 201 to 20n of FIG. 1, as shown in FIG. 8, a plurality of shift circuits 301 to 30n respectively include comparators 321 to 32n which compare memory output data RD1 to RDn read out from memories 311 to 31n and the signal TD providing the expected value with each other for each bit, comparison result registers 331 to 33n which capture comparison results CD1 to CDn and shift the comparison results CD1 to CDn as first data bits in synchronization with the external clock OCLK. Result analyzers 341 to 34n determine existence of defects in the memories 311 to 31n based on the comparison results CD1 to CDn captured in the comparison result registers 331 to 33n. Pass/fail flag registers 351 to 35n capture defect detection results JD1 to JDn in which the numbers of bits are smaller than those of the comparison results CD1 to CDn. The defect detection results JD1 to JDn are transmitted from the result analyzers 341 to 34n, and shift the defect detection results JD1 to JDn in synchronization with the external clock OCLK. Memory-side switching circuits 361 to 36n elect one of the comparison results CD1 to CDn shifted from the comparison result registers 331 to 33n and the defect detection results JD1 to JDn shifted from the pass/fail flag registers 351 to 35n in response to the memory-side switching signals SELa1 to SELan transmitted from the BIST circuit 11.

In the shift circuits 301 to 30n, one of the comparison result registers 331 to 33m and the pass/fail flag registers 351 to 35n are connected to one another so as to form a part of the serial shift path 180. Each of the comparison result registers 331 to 33n and the memory-side pass/fail flag registers 351 to 35n may be a part of a larger shift register or may be a larger shift register itself.

The first to n-th memory collar 31 to 3n comprise memories 311 to 31n which are to be subjected, and the plurality of shift circuits 301 to 30n. The memories 311 to 31n in the first to n-th memory collars 31 to 3n are connected to the comparators 321 to 32n respectively. The comparators 321 to 32n are connected to the comparison result registers 331 to 33n respectively. The comparison result registers 331 to 33n are connected to the result analyzers 341 to 34n respectively. The result analyzers 341 to 34n are connected to the memory-side pass/fail flag registers 351 to 35n respectively. The comparison result registers 331 to 33n and the memory-side pass/fail flag registers 351 to 35n are connected to the memory-side switching circuits 361 to 36n, respectively.

The comparators 321 to 32n of the first to n-th memory collars 31 to 3n individually compare the memory output data RD1 to RDn respectively read out from the memories 211 to 21m with bits of the signal TD providing the expected value of the memory output data RD1 to RDn, which is from the BIST unit 111, and transmit the comparison results CD1 to CDn in such a manner that “0” is transmitted when the results pass and “1” is transmitted when the results fail. Each of the comparison result registers 331 to 33n is a register for a width of the memory output.

The comparison result registers 331 to 33n of the first to n-th memory collars 31 to 3n capture the comparison results CD1 to CDn from the comparators 321 to 32n, respectively. The comparison result registers 331 to 33n shift the comparison results CD1 to CDn, respectively, in synchronization with the external clock OCLK. The result analyzers 341 to 34n of the first to n-th memory collars 31 to 3n individually input all of the comparison results CD1 to CDn of the comparison result registers 331 to 33n to an unillustrated OR logic gate therein, and generate the defect detection results JD1 to JDn for determining per unit of the memory whether the comparison results pass or fail.

The memory-side pass/fail flag registers 351 to 35n of the first to n-th memory collars 31 to 3n capture the pass/fail status JD1 to JDn, respectively, from the individual result analyzers 341 to 34n. Furthermore, the memory-side pass/fail flag registers 351 to 35n shift the defect detection results JD1 to JDn, respectively, in synchronization with the external clock OCLK. Note that an unillustrated result analyzer of the BIST unit 111 determines a pass/fail status of all of the memories based on the defect detection results JD1 to JDn captured in the memory-side pass/fail flag registers 351 to 35n, and outputs the defect detection result RSLT. Unillustrated memory collars connected to the second to m-th BIST circuits 12 to 1m have similar configurations to those of the first to n-th memory collars 31 to 3n, and other configurations shown in FIG. 8 are substantially similar to those of the semiconductor integrated circuit shown in FIG. 1, and accordingly, repetitive description will be omitted.

According to the semiconductor integrated circuit shown in FIG. 8, at the time of the BIST, the chip enable signals CEN1 to CENn transmitted, for example, to the memories 311 and 313 to 31n of the BIST circuit 11, which exclude the memory 312, and the chip enable signals individually transmitted to the unillustrated memories connected to the second to m-th BIST circuits 12 to 1m, all of which are not to be subjected to the BIST, are turned off. Accordingly, the BIST operations are not executed there. Therefore, power consumption at the time of the BIST can be reduced. In the second to m-th BIST circuits 12 to 1m which are not to be subjected to the BIST, only one bit of each of the pass/fail flag registers 172 to 17m is adapted to form a part of the shift path 180. The memory 312 to be subjected to the BIST can be arbitrarily selected externally by use of the BIST configration registers 121 to 12m. Accordingly, the scheduling of the BIST, considering the power consumption and the time required for the BIST, can be performed even after the first to m-th BIST circuits 11 to 1m are installed in the semiconductor integrated circuit.

At the time of the fault diagnosis, the shift path 180 partially composes only one bit of each of the memory-side pass/fail flag registers 351 and 353 to 35n excluding the memory-side pass/fail flag register 352 in the memory collars 31 and 33 to 3n excluding the second memory collar 22, which include the memories 311 and 313 to 31n excluding the memory 312, the memories 311 and 313 to 31n not being subjected to the fault diagnosis. Furthermore, the shift path 180 partially composes only one bit of each of the pass/fail flag registers 172 to 17m in the second to m-th BIST circuits 12 to l1 which are not to be subjected to the fault diagnosis. Accordingly, the steps required for the shift can be reduced, and a tester execution time required for the fault diagnosis can be substantially shortened. Still further, the chip enable signals transmitted to the memories which are not to be subjected to the fault diagnosis are turned off, and the memories do not operate. Therefore, power consumption can be reduced.

### Third Embodiment

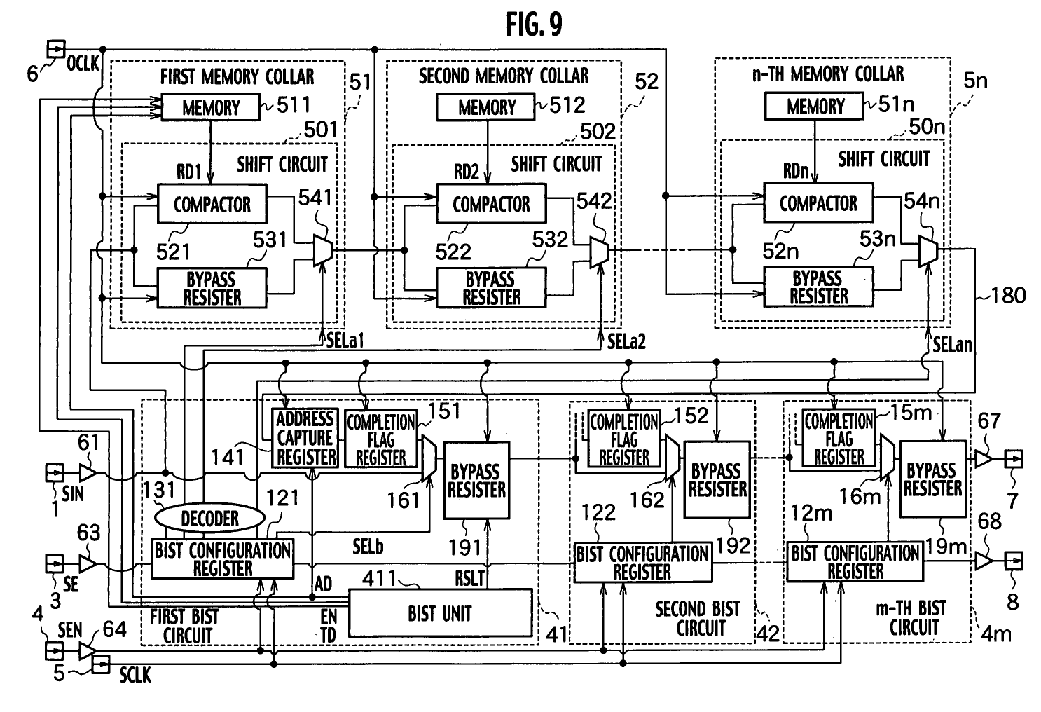

A semiconductor integrated circuit according to a third embodiment of the present invention is different from the semiconductor integrated circuit according to the first embodiment in the following point. Specifically, unlike the shift circuits 201 to 20n in FIG. 1, as shown in FIG. 9, a plurality of shift circuits 501 to 50n respectively include compactors 521 to 52n configured to perform a first operation mode so as to compact and capture the memory output data RD1 to Rdn read out from the memories 511 to 51n and to perform a second operation mode so as to directly capture the memory output data RD1 to RDn. The compactors 521 to 52n shift the memory output data RD1 to RDn in synchronization with the external clock OCLK. Bypass registers 531 to 53n shift bits having a smaller number of bits than those of the memory output data RD1 to RDn in synchronization with the external clock OCLK. BIST-side switching circuits 541 to 54n elect one of the memory output data RD1 to RDn shifted from the compactors 521 to 52n and the bits transmitted from the bypass registers 531 to 53n in response to the memory-side switching signals SELa1 to SELan transmitted from the BIST circuit 41.

In the shift circuits 501 to 50n, one of the compactors 521 to 52n and the bypass registers 531 to 53n are connected to one another, thereby forming a part of the serial shift path 180. Each of the compactors 501 to 50n and the bypass registers 531 to 53n may be a part of a larger shift register or may be a larger shift register itself.

The plurality of memories 511 to 51n and the plurality of shift circuits 501 to 50n respectively connected to the memories 511 to 51n are included in first to n-th memory collars 51 to 5n, respectively. Moreover, second to m-th BIST circuits 42 to 4m and a plurality of unillustrated memory collars individually connected to the second to m-th BIST circuits 42 to 4m are provided.

The BIST-side switching circuits 541 to 54n are connected to the respective compactors 521 to 52n and respective bypass registers 531 to 53n of the first to n-th memory collars 51 to 5n, respectively. The compactor 521 and the bypass register 531 are connected in parallel to each other between the shift path input terminal 1 and the BIST-side switching circuit 541. The address capture register 141 of the first BIST circuit 41 is connected to the BIST-side switching circuit 54n.

As the compactors 521 to 52n, referring to such as “Built-In Test for VLSI: Pseudo Random Techniques, Paul H. Bardell, William H. McAnney and Jacob Savir, John Wiley & Sons 1987”, a multi-input shift register (MISR) which is a modification of a linear feedback shift register (LFSR) is generally adapted. Each of the bypass registers 531 to 53n of the first to n-th memory collars 51 to 5n, which form a shift register structure, has one or more bits which is smaller than the number of bits of the compactors 521 to 52n. Since unillustrating memory collars are connected to the second to m-th BIST circuits 42 to 4m are substantially similer to the first to n-th memory collars 51 to 5n, a redundant description will be omitted.

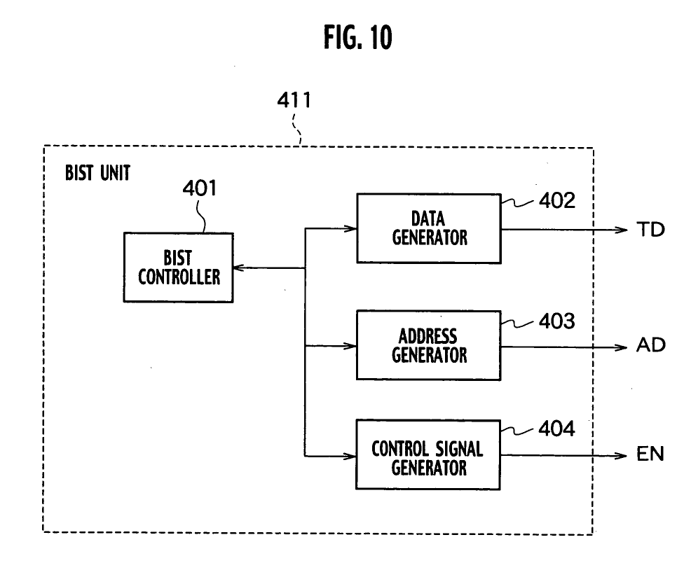

As shown in FIG. 10, the BIST unit 411 in the first BIST circuit 41 includes a BIST controller 401, a data generator 402, an address generator 403 and a control signal generator 404. The BIST controller 401 controls the data generator 402, the address generator 403 and the control signal generator 404 to generate the memory write data TD, the memory address data AD and the memory control signal EN respectively, if needed. The test result is determined by comparing the values shifted out from the shift path output terminal 7 with the expected values stored in the memory of external test apparatus. As shown in FIG. 9, in the case of performing BIST of one BIST circuit, for example, the first BIST circuit 41 having the plurality of memories 511 to 51n, the respective compactors 521 to 52n are serially connected to each other, and connected to the BIST circuit 41. Since the other configurations of the semiconductor integrated circuit shown in FIG. 9 are substantially similer to the semiconductor integrated circuit shown in FIG. 1, a redundant description will be omitted.

At the time of the BIST for the semiconductor integrated circuit shown in FIG. 9, because an operation mode is the BIST mode, the operation mode setting bits of the BIST configration registers 121 to l1 are again set to “0”. In the memory selecting bit string of the BIST configration register 121, a bit corresponding, for example, to the memory 511 to be subjected to the BIST is set to “1”, and bits of the BIST configration register 121, which correspond to the memories 512 to 51n which are not to be subjected to the BIST, are set to “0”. An operation enable bit of the BIST configration register 121 of the first BIST circuit 41 to be subjected to the BIST is set to “1”, and in the BIST configration registers 122 to 12m of the second to m-th BIST circuits 42 to 4m which are not to be subjected to the BIST, operation enable bits are set to “0”.

At the time of the BIST operation, the memory write data TD, the memory address data AD and the memory control signal EN, which are respectively obtained from the data generator 402, the address generator 403 and the control signal generator 404 are transmitted to the memory 511 as shown in FIG. 9. The memory output data RD1 read out from the memory 511 is transmitted to the compactor 521, and is sequentially compacted. The chip enable signals input to the memories 512 to 51n excluding the memory 511 and to unillustrated memories connected to the second to m-th BIST circuits 42 to 4m are controlled to be OFF. Accordingly, the BIST operations are not executed.

Subsequently, after the end of the BIST operation, a compaction result CRD1 of the compactor 521 and contents of the bypass register 191, in which the number of bits for bypass is small, are shifted out through the shift path output terminal 7 in synchronization with the external clock OCLK. Here, the switching circuits 162 . . . and 16m of the second to m-th BIST circuits 42 to 4m allow shift paths in the second to m-th BIST circuits 42 to 4m to comprise only one bit of each of the bypass registers 192 to 19m. The shifted-out value stored in the compactor 521 and an expected value previously calculated as a test result are compared with each other externally, and existence of defects in the memory 511 is determined.

At the time of the fault diagnosis of the semiconductor integrated circuit shown in FIG. 9, because the operation mode is the fault diagnosis mode, the operation mode setting bits of the BIST configration registers 121 to 12m are set to “1”. In the memory selecting bit string of the BIST configration register 121, a bit corresponding, for example, to the memory 511 to be subjected to the fault diagnosis is set to “1”, and bits corresponding to the memories 512 to 51n which are not to be subjected to the fault diagnosis are set to “0”. An operation enable bit of the first BIST circuit 41 to be subjected to the fault diagnosis is set to “1”, and in the BIST configration registers 122 to 12m of the second to m-th BIST circuits 42 to 4m which are not to be subjected to the fault diagnosis, operation enable bits are set to “0”. Then, at the time of the BIST operation, the memory write data TD, the memory address data AD and the memory control signal EN from the BIST unit 411 are transmitted to the memory 511. The memory output data RD1 read out from the memory 511 is directly captured in the compactor 521. The chip enable signals transmitted to the memories 512 to 51n excluding the memory 511 and to the unillustrated memories connected to the second to m-th BIST circuits 42 to 4m are controlled to be OFF. Accordingly, the BIST operations are not executed.

After the BIST operation is interrupted, the external shift signal SIN is input from the shift path input terminal 1 in synchronization with the external clock OCLK, the shift operation is performed for the serial shift path 180, and a value of the shift path 180 is shifted out through the shift path output terminal 7. Here, the BIST-side switching circuit 541 of the first memory collar 51 directly transmits the memory output data RD1 to the compactor 521. The BIST-side switching circuits 542 to 54n of the second to n-th memory collars 52 to 5n transmit the bits of the bypass registers 532 to 53n. After the shift out, the BIST operation is resumed. The interruption of the BIST operation, the shift out, and the resumption of the BIST operation are repeated, a fail bit map is created based on the shifted-out values, and bit positions of the faulty locations of the memory 511 are analyzed.

According to the third embodiment of the present invention, even in a case where the compaction BIST circuits 41 to 4m are used instead of the comparative BIST circuit 11 to 1m, in the second to n-th memory collar 52 to 5n having the memories 512 to 51n which are not to be subjected to the fault diagnosis, the shift path having one bit in the bypass registers 532 to 53n is formed. Therefore, it is possible to greatly reduce the time required for the fault diagnosis, and the size of a test pattern can be reduced.

Furthermore, in the second to m-th BIST circuit 42 to 4m which are not to be subjected to the BIST and the fault diagnosis, the bypass registers 532 to 53n having a smaller number of bits than a register of a compactors 521 to 52n form a part of the shift path 180. Therefore, power consumption can be reduced. Furthermore, it is possible to schedule the test freely by selecting a desired memory or BIST circuit, such as the memory 511 or the first BIST circuit 41, which is to be subjected to the BIST or the fault diagnosis.

### Other Embodiment

The serial setting input terminal 3 shown in FIG. 1 which inputs bits serialy to the BIST configration registers 121 to 12m, the serial setting output terminal 8 which outputs bits serialy from the BIST configration registers 121 to 12m, the shift path input terminal 1 and the shift path output terminal 7 for fault diagnosis result or result observation may be respectively connected to a standard test access port which is standardized by “IEEE Std 1149.1-2001 Standard Test Access Port and Boundary-Scan Architecture”.

Various modifications will become possible for those skilled in the art after receiving the teachings of the present disclosure without departing from the scope thereof.

What is claimed is:

1. A semiconductor integrated circuit comprising:
a plurality of memories;
a BIST circuit configured to test at least one of the memories; and
a plurality of shift circuits connected to each of the memories, each of the shift circuits shifts one of first data bits obtained from at least one of the memories and a second data bits having a smaller number of bits than the first data bits, in synchronization with an external clock, by electing one of the first and second data bits in accordance with a swiching signal from the BIST circuit;
wherein the shift circuits are connected to one another so as to form a part of a serial shift path.

2. The semiconductor integrated circuit of claim 1, wherein the BIST circuit test the more than two memories.

3. The semiconductor integrated circuit of claim 1, wherein the BIST circuit comprises a test configration register storing a bit string, configured to generate the swiching signal.

4. The semiconductor integrated circuit of claim 3, wherein the bit string is transmitted from an external terminal.

5. The semiconductor integrated circuit of claim 1, further comprising a test configration register storing a bit string configured to control a chip enable signal of the memory.

6. The semiconductor integrated circuit of claim 1, further comprising a test configration register storing a bit string configured to control a clock signal of the memory.

7. The semiconductor integrated circuit of claim 1, wherein the swiching signal is individually generated for each of the shift circuits.

8. The semiconductor integrated circuit of claim 1, wherein each of the swiching signal is generated for a group of shift circuits.

9. The semiconductor integrated circuit of claim 1, wherein all or a part of the memories to be tested are set by an external signal at a time.

10. The semiconductor integrated circuit of claim 1, further comprising another BIST circuit configured to test another memory in the memories.

11. The semiconductor integrated circuit of claim 1, wherein the BIST circuit comprises:
a BIST unit generating write data, and generating a pass/fail based on memory output data read out from at least one of the memories in accordance with the write data; and
a pass/fail flag register holding the pass/fail, and forming another part of the shift path.

12. The semiconductor integrated circuit of claim 1, wherein the BIST circuit comprises:
a first path connected to the shift circuit;
a second path transmitting a signal having smaller number of bits than a signal transmitting the first path; and
a BIST-side switching circuit configured to assign one of the first and second paths so as to form another part of the serial shift path in accordance with a second switching signal.

13. The semiconductor integrated circuit of claim 12, wherein a chip enable signal of the memory subject to the BIST circuit is turned off when the BIST circuit shifts the signal in the second path.

14. The semiconductor integrated circuit of claim 12, wherein a clock signal of the memory subject to the BIST circuit is turned off when the BIST circuit shifts the signal in the second path.

15. The semiconductor integrated circuit of claim 12, wherein the first path comprises an address capture register configured to capture address data identifying an address of the memory to which the write data is written.

16. The semiconductor integrated circuit of claim 12, further comprising a test configration register storing a bit string configured to control the second switching signal.

17. The semiconductor integrated circuit of claim 16, wherein the bit string is transmitted from an external terminal to the test configration register.

18. The semiconductor integrated circuit of claim 1, wherein each of the shift circuits comprises:
a memory output capture register configured to capture memory output data as the first data bits, reading out from at least one of the memories and to shift the first data bits in syncronization with the external clock;
a comparator configured to compare the first data bits captured by the memory output capture register with an expected value transmitted from the BIST circuit;
a comparison flag register configured to capture the second data bits as a comparison result, from the comparator, and shifting the comparison result in syncronization with the external clock; and
a memory-side switching circuit configured to elect one of the first data bits from the memory output capture register and the second data bits from the comparison flag register, in accordance with the swiching signal.

19. The semiconductor integrated circuit of claim 1, wherein each of the shift circuits comprises:
a comparator configured to compare memory output data from at least one of the memories and an expected value from the BIST circuit for each bit;
a comparison result register configured to capture the first data bits from the comparator as a comparison result, and to shift the comparison result in syncronization with the external clock;
a result analyzer configured to determine a existence of defects in at least one of the memories based on the comparison result from the comparison result register;
a pass/fail flag register configured to capture a pass/fail status as the second data bits from the result analyzer and shifting the second data bits in syncronization with the external clock; and
a memory-side switching circuit configured to elect one of the comparison result from the compactor and the second data bits from the pass/fail flag register, in accordance with the memory swich signal.

20. The semiconductor integrated circuit of claim 1, wherein each of the shift circuits comprises:
a compactor configured to perform a first operation mode so as to compact and to capture memory output data from at least one of the memories and to perform a second operation mode so as to directly capture memory output data from at least one of the memories, and to shift the memory output data as the first data bits in syncronization with the external clock;
a bypass register cofigured to shift the second data bits in syncronization with the external clock; and
a memory-side switching circuit configured to elect one of the first data bits from the compactor and the second data bits from the bypass register, in accordance with the memory swich signal.
